(19) United States
(12) Patent Application Publication
(10) Pub. No.: US 2012/0027953 A1
(43) Pub. Date: Feb. 2, 2012

(54) Rotating Reactor Assembly for Depositing Film on Substrate

(75) Inventor: Sang In LEE, Sunnyvale, CA (US)

(73) Assignee: SYNOS TECHNOLOGY, INC., Sunnyvale, CA (US)

(21) Appl. No.: 13/190,104

(22) Filed: Jul. 25, 2011

Related U.S. Application Data
(60) Provisional application No. 61/368,442, filed on Jul. 28, 2010.

(51) Int. Cl. C23C 16/455; C23C 16/50

(52) U.S. Cl. 427/569; 118/715; 118/723 R; 427/248.1

(57) ABSTRACT

A rotating reactor assembly includes an injector rotor comprising a channel extending in a direction parallel to a rotational axis of the injector rotor and at least one injection hole connected to the channel; and an intake port through which a material is introduced. As the injector rotor rotates, the channel is timely and/or periodically connected to the intake port such that the material is injected to a substrate through the at least one injection hole.

### CROSS-REFERENCE TO RELATED APPLICATION

This application claims priority under 35 U.S.C. §119(e) to co-pending U.S. Provisional Patent Application No. 61/368,442, filed on Jul. 28, 2010, which is incorporated by reference herein in its entirety.

### BACKGROUND

1. Field of Art

The present invention relates to a rotating reactor assembly for performing atomic layer deposition.

2. Description of the Related Art

A conventional scan-type atomic layer deposition (ALD) apparatus deposits a single atomic layer on a substrate with linear motion of the substrate relative to the depositing apparatus or with linear motion of the depositing apparatus relative to the substrate. During the operation, the scan-type ADL apparatus injects precursors onto the substrate. For example, the bottom of the ALD apparatus has injectors for injecting precursor materials on the top surface of the substrate. The substrate may undergo multiple iterations of linear motion relative to the scan-type ALD apparatus to deposit multiple atomic layers on the substrate.

The speed of depositing a desired number of atomic layers to obtain an ALD film of a predetermined thickness depends on the linear moving speed of the substrate or the ALD apparatus. However, due to the limited speed and control constraints, various technical challenges are encountered when the relative linear speed between the substrate and the ALD apparatus exceeds a certain limit.

One way of increasing the speed of depositing multiple atomic layers is to increase the number of injector modules in the ALD apparatus. The scan-type ALD apparatus may include multiple injector modules or multiple scan-type atomic layer deposition apparatuses placed adjacent to each other so that a single linear movement of the substrate allows multiple atomic layers to be deposited on the substrate. However, the increased number of injector modules or the ALD apparatuses increases space requirement and also costs associated with the ALD apparatuses.

### SUMMARY

Embodiments relate to a rotating reactor assembly including an injector rotor with a channel extending in along a rotational axis of the injector rotor and at least one injection hole connected to the channel. An intake port is provided in the rotating reactor assembly through which a material is introduced. As the injector rotor rotates, the channel is timely and/or periodically connected to the intake port such that the material is injected to a substrate through the at least one injection hole.

### BRIEF DESCRIPTION OF DRAWINGS

FIG. 1 is a perspective view of a rotating reactor assembly according to one embodiment.

FIG. 2A is a cross-sectional view of the rotating reactor assembly of FIG. 1, taken along line A-A′, according to one embodiment.

FIG. 2B is a perspective view of an injector rotor of FIG. 2A, according to one embodiment.

FIG. 3A is an exploded view of a rotating reactor assembly according to one embodiment.

FIG. 3B is a bottom view of a rotating reactor assembly according to one embodiment.

FIG. 3C is a top view of a rotating reactor assembly according to one embodiment.

FIGS. 4A through 4D are cross-sectional views of a rotating reactor assembly according to one embodiment in various phases.

FIGS. 5A through 5D are diagrams illustrating deposition patterns obtained using a rotating reactor assembly according to one embodiment.

FIGS. 6A and 6B are diagrams illustrating films deposited using a rotating reactor assembly, according to one embodiment.

FIGS. 7 through 9 are cross-sectional views of rotating reactor assemblies according to embodiments.

FIGS. 10A through 10E are cross-sectional views of a rotating reactor assembly according to one embodiment in various phases.

FIG. 11A is a longitudinal cross-sectional view of a rotating reactor assembly according to one embodiment.

FIG. 11B is a transverse cross-sectional view of a manifolding plate of the rotating reactor assembly of FIG. 11A.

FIG. 12A is a longitudinal cross-sectional view of a rotating reactor assembly according to one embodiment.

FIG. 12B is a transverse cross-sectional view of a joint portion of an intake opening and a channel of the rotating reactor assembly of FIG. 12A.

FIGS. 13A through 13C are cross-sectional views of a rotating reactor assembly according to one embodiment in various phases.

FIG. 14 is a cross-sectional view of a rotating reactor assembly according to one embodiment.

FIGS. 15A through 15E are cross-sectional views of a rotating reactor assembly according to one embodiment in various phases.

FIGS. 16A through 16C are cross-sectional views of rotating reactor assemblies according to embodiments.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

The terminology used herein is for the purpose of describing particular exemplary embodiments only and is not intended to be limiting of this disclosure. As used herein, the singular forms “a”, “an” and “the” are intended to include the plural forms as well, unless the context clearly indicates otherwise. Furthermore, the use of the terms a, an, etc. does not denote a limitation of quantity, but rather denotes the presence of at least one of the referenced item. The use of the terms “first”, “second”, and the like does not imply any particular order, but they are included to identify individual elements. Moreover, the use of the terms first, second, etc. does not denote any order or importance, but rather the terms first, second, etc. are used to distinguish one element from another. It will be further understood that the terms “comprises” and/or “comprising”, or “includes” and/or “including” when used in this specification, specify the presence of stated features, regions, integers, steps, operations, elements, and/or components, but do not preclude the presence or addition of at least one other features, regions, integers, steps, operations, elements, components, and/or groups thereof.

In the drawings, like reference numerals in the drawings denote like elements. The shape, size and regions, and the like, of the drawing may be exaggerated for clarity.

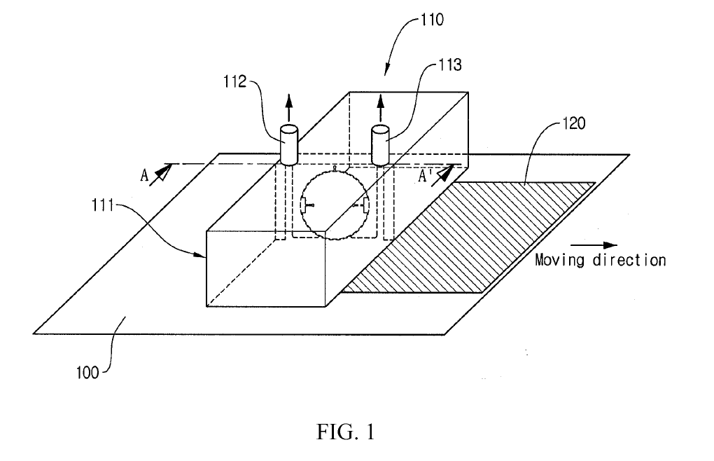

FIG. 1 is a perspective view of a rotating reactor assembly 110 according to one embodiment. A substrate 100 may move relative to a rotating reactor assembly 110. For this purpose, the substrate 100 may be mounted on a support (not shown). The movement of the substrate 100 relative to the rotating reactor assembly 110 may be a linear or rotational motion, but is not limited thereto. Although an example process of performing deposition by moving the substrate 100 relative to the rotating reactor assembly 110 is described in this embodiment, in other embodiments, the substrate 100 may be fixed and the rotating reactor assembly 110 may move relative to the substrate 100. While the substrate 100 passes through the rotating reactor assembly 110, a film 120 including one or more atomic layers may be formed on the substrate 100.

Materials such as a source precursor, a reactant precursor and a purge gas may be supplied from an external source (not shown) into the rotating reactor assembly 110. The materials may be supplied through a conduit (not shown) connected to the rotating reactor assembly 110. The supplied materials may be injected to the substrate 100 passing through the rotating reactor assembly 110 by the rotating reactor assembly 110. The rotating reactor assembly 110 may include a housing 111 enclosing the rotating reactor assembly 110, and excess materials may be discharged out of the rotating reactor assembly 110 through exhaust portions 112, 113.

The rotating reactor assembly 110 according to one embodiment may be disposed in a deposition apparatus such as an ALD apparatus. The rotating reactor assembly 110 may operate at a pressure lower than the atmospheric pressure. For example, the rotating reactor assembly 110 may be operated in vacuum state. For this purpose, the pressure of the portion of the deposition apparatus where the rotating reactor assembly 110 is disposed may be controlled adequately according to a deposition process by the rotating reactor assembly 110. And, the portion of the deposition apparatus where the rotating reactor assembly 110 is disposed may be filled with a material that does not react with the material (e.g., the source precursor, the reactant precursor, and the purge gas) injected to the substrate by the rotating reactor assembly 110. For example, the apparatus may be filled with Ar, He, N₂ or H₂ gas.

The rotating reactor assembly 110 according to one embodiment may be disposed in plural numbers in one deposition apparatus. In this case, apparatuses for performing different semiconductor manufacturing processes may be provided in the space between the rotating reactor assemblies 110. For example, a heating device for heat-treating the substrate or a plasma-generating device for treating the substrate with a plasma may be provided between one rotating reactor assembly 110 and the next rotating reactor assembly 110 in the ALD apparatus. As such, by providing other process-related apparatuses together with the rotating reactor assembly 110 according to one embodiment in the ALD apparatus, the flexibility of the semiconductor manufacturing process can be improved without significantly increasing the complexity and size of the ALD apparatus.

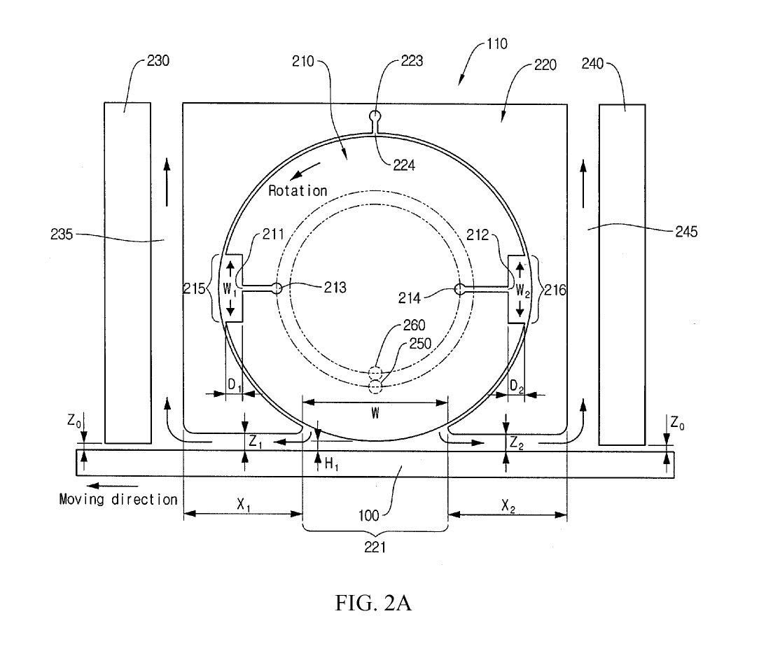

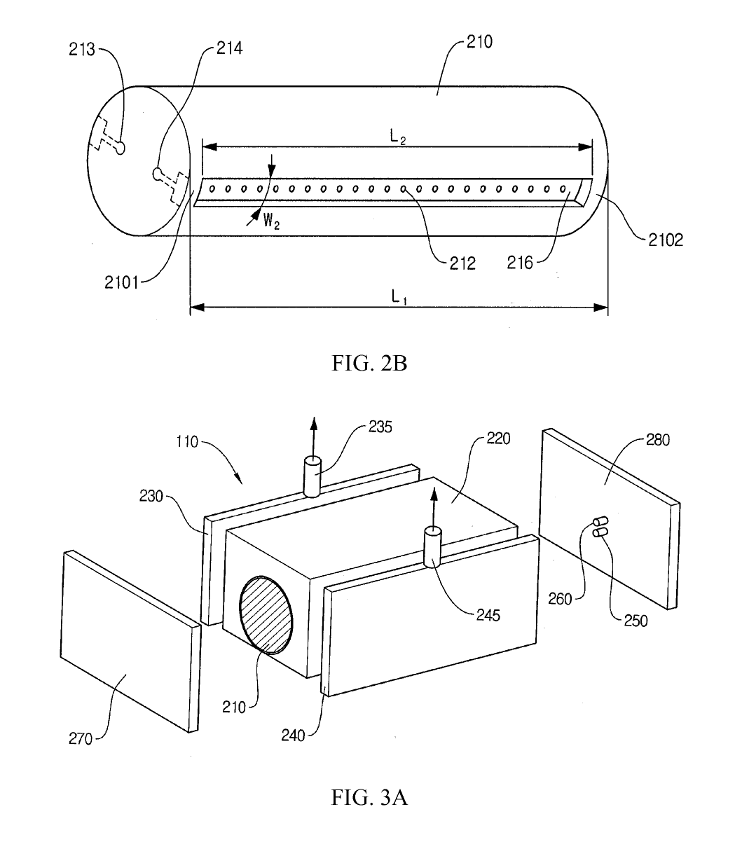

FIG. 2A is a cross-sectional view of the rotating reactor assembly shown in FIG. 1, along line A-A′. The rotating reactor assembly 110 may include, among other components, an injector rotor 210, a housing 220 enclosing the injector rotor 210 and side walls 230, 240. All or part of the housing 220 and the side walls 230, 240 may be formed integrally, but the present invention is not limited thereto.

The injector rotor 210 may be installed in a cavity formed in the housing 220. An opening 221 may be formed at the bottom portion of the housing 220. The surface of the injector rotor 210 exposed through the opening 221 may be spaced apart from the nearest portion of the substrate 100 by a spacing H₁. A material may be injected by the injector rotor 210 to the substrate therebelow through the opening 221 of the housing 220. Excess material of the injected material may be pumped out of the rotating reactor assembly 110 through exhaust portions 235, 245 located between the housing 220 and the side walls 230, 240.

The injector rotor 210 may rotate in the housing 220 at a predetermined angular speed. While the substrate 100 passes below the rotating injector rotor 210, a film may be formed on the substrate 100 by the material injected by the injector rotor 210. In one embodiment, the moving direction of the substrate 100 is the same as the rotating direction of the injector rotor 210. That is to say, while the substrate 100 passes below the injector rotor 210, the surface of the injector rotor 210 facing the substrate 100 may move in the same direction as the moving direction of the substrate 100. However, in another embodiment, the moving direction of the substrate 100 may be opposite to the rotating direction of the injector rotor 210. That is, while the substrate 100 passes below the injector rotor 210, the surface of the injector rotor 210 facing the substrate 100 may move in a direction opposite to the moving direction of the substrate 100.

The injector rotor 210 may have a channel and one or more injection hole(s) connected thereto. In one embodiment, the injector rotor 210 may have one or more first injection hole(s) 211 and one or more second injection hole(s) 212. The one or more first injection hole(s) 211 may be connected to a first channel 213. Similarly, the one or more second injection hole(s) 212 may be connected to a second channel 214. The first channel 213 and the second channel 214 may extend in a longitudinal direction. In one embodiment, The first channel 213 and the second channel 214 extend parallel to the rotational axis of the injector rotor 210. For example, if the injector rotor 210 has a cylindrical shape, the first channel 213 and the second channel 214 may be formed in the injector rotor 210 and extend along the length direction of the cylinder.

While the injector rotor 210 rotates, only the first channel 213 may be connected to a first intake port 250, and the second channel 214 may be disconnected from the first intake port 250. Likewise, only the second channel 214 may be connected to a second intake port 260, and the first channel 213 may not be disconnected from the second intake port 260. The first channel 213 and the first intake port 250 may be disposed in locations that are a first distance away from the rotational axis of the injector rotor 210, and the second channel 214 and the second intake port 260 may be disposed in locations that are a second distance away from the rotational axis of the injector rotor 210. That is, the first channel 213 and the first intake port 250 may be arranged on a circumference in a cross-section perpendicular to the length direction of the injector rotor 210, and the second channel 214 and the second intake port 260 may be arranged on another circumference different therefrom.

The one or more first injection hole(s) 211 may be disposed in a first recess 215 formed on the surface of the injector rotor 210. For example, the injector rotor 210 may have a cylindrical shape, and the first recess 215 may be formed on the bent side surface of the injector rotor 210. Similarly, the one or more second injection hole(s) 212 may be disposed in a second recess 216 formed on the surface of the injector rotor 210. For example, the first recess 215 and the second recess 216 may be formed in the shape of a rectangular parallelepiped formed on the surface of the injector rotor 210 along the length direction of the injector rotor 210. However, the present invention is not limited thereto.

The one or more first injection hole(s) 211 and the one or more second injection hole(s) 212 may be arranged in a direction parallel to the rotational axis of the injector rotor 210. The one or more first injection hole(s) 211 may be spaced from one another. And, the one or more second injection hole(s) 212 may be spaced from one another. Meanwhile, the one or more second injection hole(s) 212 may be spaced from the one or more first injection hole(s) 211.

The rotating reactor assembly 110 may include one or more intake port(s) for injecting the material to the substrate. In one embodiment, the rotating reactor assembly 110 includes a first intake port 250 and a second intake port 260. The first intake port 250 and the second intake port 260 may be connected to sources (not shown) supplying different materials. As the injector rotor 210 rotates, the first channel 213 may be connected to the first intake port 250 in accordance with the rotation speed of the injector rotor 210, such that the material introduced through the first intake port 250 may be injected to the substrate 100 through the one or more first injection hole(s) 211. Likewise, as the injector rotor 210 rotates, the second channel 214 may be connected to the second intake port 260 in accordance with the rotation speed of the injector rotor 210, such that the material introduced through the second intake port 260 may be injected to the substrate 100 through the one or more second injection hole(s) 212.

When the first recess 215 is located below the housing 220 as the injector rotor 210 rotates, the first channel 213 may be connected to the first intake port 250. Then, a first material introduced through the first intake port 250 may be transferred through the first channel 213 and then injected through the one or more first injection hole(s) 211 to fill the first recess 215. For example, the first material may be a source precursor for depositing an atomic layer, but is not limited thereto. Subsequently, as the injector rotor 210 rotates, the first material may be injected to the substrate 100.

When the second recess 216 is located below the housing 220 as the injector rotor 210 further rotates, the second channel 214 may be connected to the second intake port 260. As a result, a second material introduced through the second intake port 260 may be filled in the second recess 216. The second material may be a reactant precursor for forming an atomic layer, but is not limited thereto. When the second recess 216 is already filled with a purge gas prior to the injection of the second material, the second material pushes out the purge gas and fills the second recess 216. Subsequently, as the injector rotor 210 rotates further, the second material may be injected to the substrate 100.

The opening 221 of the housing 220 may have a width W. And, the first recess 215 and the second recess 216 formed on the injector rotor 210 may have widths W₁ and W₂, respectively. In one embodiment, the widths W₁ and W₂ of the first recess 215 and the second recess 216 are smaller than the width W of the opening 221 of the housing 220. However, the present invention is not limited thereto.

In one embodiment, the housing 220 includes a channel 223 and one or more injection hole(s) 224 connected to the channel 223. A purge gas may be injected between the injector rotor 210 and the housing 220 through the channel 223 and the one or more injection hole(s) 224. For example, the purge gas may be Ar gas, but is not limited thereto. In one embodiment, the channel 223 and the one or more injection hole(s) 224 may be provided at the upper portion of the housing 220, so that the purge gas may be injected downward to the injector rotor 210. The injected purge gas may flow through a space between the injector rotor 210 and the housing 220 and be discharged through the opening 221 of the housing 220. Subsequently, the purge gas may travel flow through a space between the bottom surface of the housing 220 and the substrate 100 and be discharged outward through the exhaust portions 235, 245.

By passing the purge gas through the narrow gap between the substrate 100 and the housing 220, an excess precursor material (e.g., a layer of precursor material physically (not chemically) adsorbed on the substrate 100) may be removed from the surface of the substrate 100. Distances X₁ and X₂ from both ends of the opening 221 of the housing 220 to the adjacent exhaust portions 235, 245 along the moving direction of the substrate 100 and the corresponding heights z₁ and z₂ may be determined adequately depending on the properties of the film to be deposited. And, the purge gas may remove the excess material remaining in the first recess 215 and the second recess 216 of the injector rotor 210, so as to prevent the materials injected through the first intake port 250 and the second intake port 260 from reacting with each other between the injector rotor 210 and the housing 220.

The lower ends of the side walls 230, 240 may be spaced apart from the substrate 100 by a spacing z₀. In one embodiment, the pressure inside the rotating reactor assembly 110 may be higher than the pressure outside the rotating reactor assembly 110. As a result, a material may flow out of the rotating reactor assembly 110 through the gap between the lower ends of the side walls 230, 240 and the substrate 100. Especially, a purge gas flowing out of the rotating reactor assembly 110 may act as a gas curtain which prevents impurities from influencing the deposition process by the rotating reactor assembly 110. In one embodiment, a ferrofluid may be provided between the lower ends of the side walls 230, 240 and the substrate 100 in order to prevent the material from leaking out of the rotating reactor assembly 110.

FIG. 2B is a perspective view of the injector rotor of FIG. 2A, according to one embodiment. The injector rotor 210, the first channel 213 and the second channel 214 may extend along the rotational axis of the injector rotor 210. The second recess 216 formed on the injector rotor 210 may be formed as a groove having a length L₂ along a direction parallel to the rotational axis of the injector rotor 210. The length L₂ of the second recess 216 may be smaller than the length L₁ of the injector rotor 210. As a result, clearance portions 2101, 2102 where a film is not deposited may be formed at both ends of the second recess 216 along a direction parallel to the rotational axis of the injector rotor 210. The first recess 215 may also have a similar configuration as that of the second recess 216.

In a film deposition process using the rotating reactor assembly described above with reference to FIGS. 2A and 2B, the film deposition rate may be determined by various parameters related to the rotating reactor assembly. For example, the film deposition rate may be determined based on the rotation speed of the injector rotor 210, the flow rate of the source precursor and the reactant precursor introduced through the first intake port 250 and the second intake port 260, the flow rate of the purge gas introduced through the channel 223 of the housing 220, the moving speed and direction of the substrate 100, the spacing z₁, z₂ between the substrate 100 and the lower end of the housing 220, the spacing H₁ between the substrate 100 and the injector rotor 210, the width W₁ and depth D₁ of the first recess 215 and the width W₂ and depth D₂ of the second recess 216 formed in the injector rotor 210, the distance X₁, X₂ from the both ends of the opening 221 of the housing 220 to the adjacent exhaust portions 235, 245, or the like.

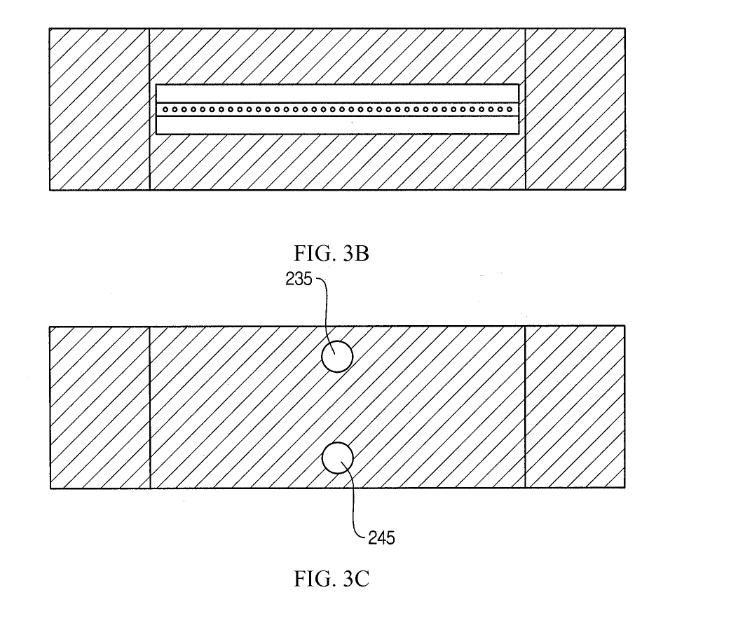

FIG. 3A is an exploded view of the rotating reactor assembly according to one embodiment, FIG. 3B is a bottom view of the rotating reactor assembly according to one embodiment, and FIG. 3C is a top view of the rotating reactor assembly according to one embodiment. A rotating reactor assembly 110 may include, among other components, an injector rotor 210, a housing 220 and covers 270, 280 provided at both ends of side walls 230, 240. The cover 280 may have a first intake port 250 and a second intake port 260. However, this is only exemplary. In another embodiment, one or more intake port(s) may be formed in the cover 270 or another portion of the rotating reactor assembly 110. The rotating reactor assembly 110 may further comprise devices such as a sealing apparatus for preventing leakage of a material which is not illustrated in FIG. 3A.

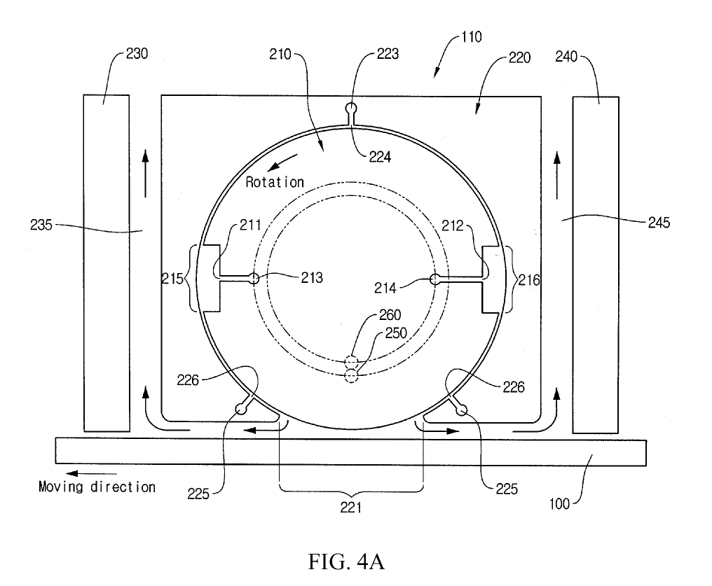

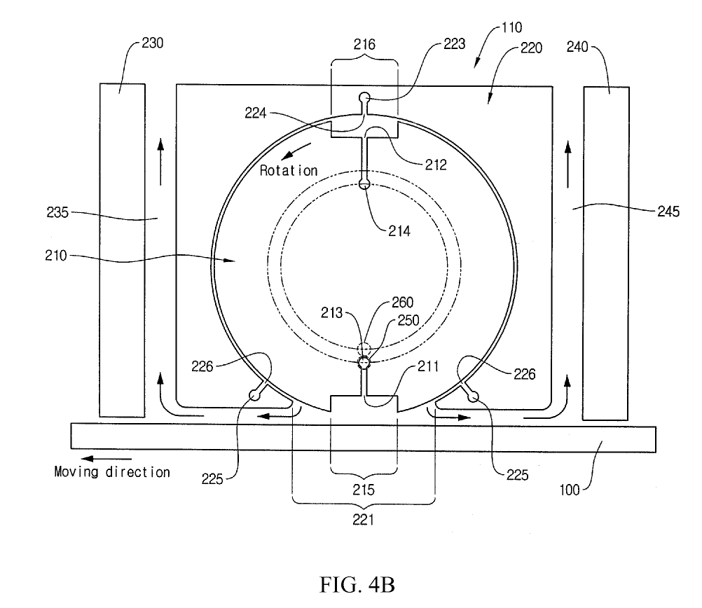

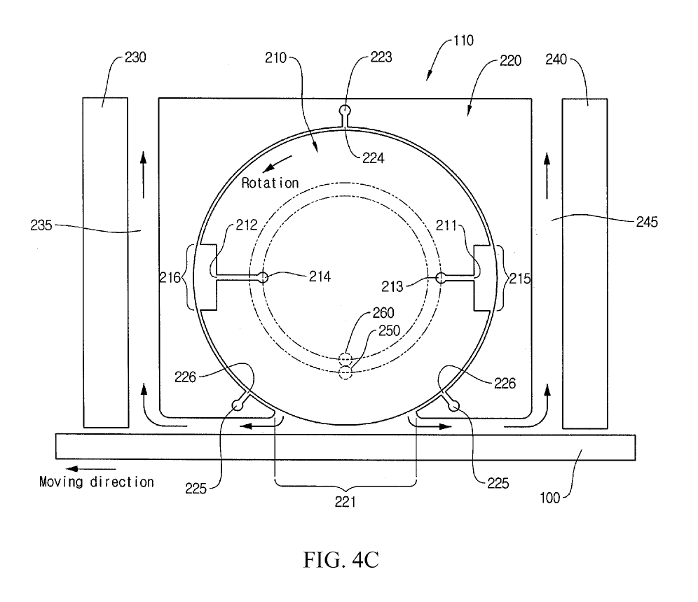

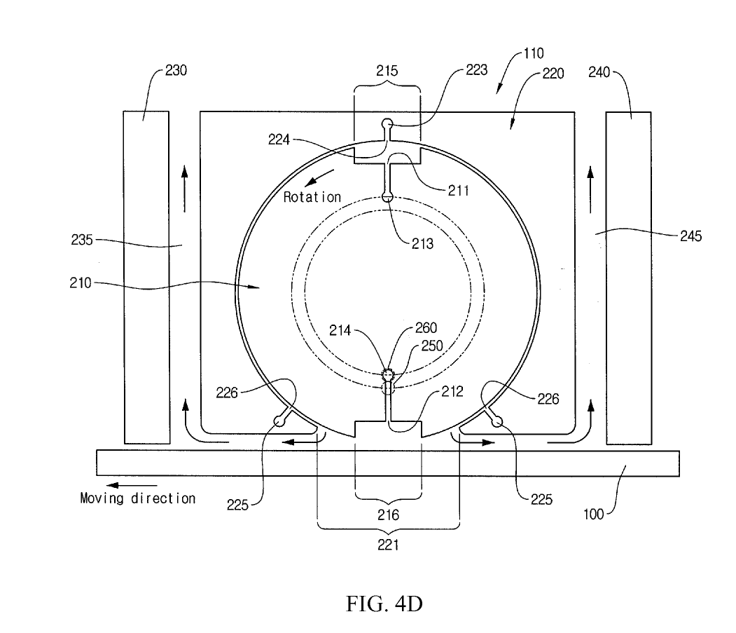

FIGS. 4A through 4D are cross-sectional views of the rotating reactor assembly according to one embodiment in various phases. The rotating reactor assembly 110 in FIGS. 4A through 4D is the same as that of the rotating reactor assembly described above with reference to FIGS. 2A and 2B, except that the housing 220 further comprises another one or more channel(s) 225 and injection hole(s) 226 respectively connected to the channel(s) 225.

One channel 225 and one or more injection hole(s) 226 connected thereto may be provided at one end of the opening 221 of the housing 220, and another channel 225 and one or more injection hole(s) 226 connected thereto may be provided at the other end of the opening 221 of the housing 220. The function of the channel 225 and the one or more injection hole(s) 226 is the same as that of the channel 223 and the one or more injection hole(s) 224 described above. Therefore, a detailed description will be omitted.

FIG. 4A is a cross-sectional view of the rotating reactor assembly according to one embodiment in a first phase. In the state where a first channel 213 and a second channel 214 are not respectively connected to a first intake port 250 and a second intake port 260, only a purge gas injected through the injection holes 224, 226 of the housing 220 exists in the space between the injector rotor 210 and the housing 220. The pressure of the purge gas injected through the injection holes 224, 226 may be larger than the pressure of a precursor injected through the intake ports 250, 260. As a result, the purge gas injected through the injection holes 224, 226 may discharge a precursor remaining from a previous deposition stage by pushing it out to exhaust portions 235, 245.

FIG. 4B is a cross-sectional view of the rotating reactor assembly according to one embodiment in a second phase. As the injector rotor 210 rotates, a first recess 215 may face a substrate 100 passing below the rotating reactor assembly 110. Then, the first channel 213 is connected to the first intake port 250, and the material introduced through the first intake port 250 may be transferred through the first channel 213 and injected to the substrate 100 through one or more first injection hole(s) 211. For example, the material introduced through the first intake port 250 may be a first precursor. The injected first precursor may be deposited on the surface of the substrate 100, and molecules physisorbed to the surface of the substrate 100 may be removed by the purge gas injected through the injection holes 224, 226. In this phase, a second recess 216 is aligned with the injection hole 224 formed on the housing 220, such that the second recess 216 is filled with the purge gas.

FIG. 4C is a cross-sectional view of the rotating reactor assembly 110 according to one embodiment in a third phase. As the injector rotor 210 rotates further from the phase illustrated in FIG. 4B, the first channel 213 is separated from the first intake port 250. The second channel 214 is not connected to the second intake port 260. Accordingly, in this phase, the precursor is not supplied to the substrate 100. The purge gas may be injected through the injection hole 226 of the housing 220, and molecules physisorbed to the surface of the substrate 100 may be removed by the purge gas.

FIG. 4D is a cross-sectional view of the rotating reactor assembly according to one embodiment in a fourth phase. As the injector rotor 210 rotates further from the phase illustrated in FIG. 4C, the second recess 216 may face the substrate 100 as illustrated in FIG. 4D. In this phase, the second channel 214 may be connected to the second intake port 260, and the material introduced through the second intake port 260 may be transferred through the second channel 214 and injected to the substrate 100 through the one or more second injection hole(s) 212. For example, the material introduced through the second intake port 260 may be a second precursor. The injected second precursor may react with the first precursor adsorbed in the surface of the substrate 100 to form a film on the substrate 100. Meanwhile, molecules physisorbed on the surface of the substrate 100 may be removed by the purge gas injected through the injection holes 224, 226. In this phase, the first recess 215 is aligned with the injection hole 224 formed on the housing 220, such that the first recess 215 is filled with the purge gas.

When the injector rotor 210 rotates further from the fourth phase shown in FIG. 4D, it returns to the first phase described above with reference to FIG. 4A. Every time the injector rotor 210 rotates once, the first through fourth phases described referring to FIGS. 4A through 4D may proceed sequentially. This procedure may be performed repeatedly until a film of desired thickness is deposited. The state of the substrate in the first through fourth phases described referring to FIGS. 4A through 4D is summarized in Table 1.

TABLE 1

| Phase | Substrate |
|---|---|
| First phase: Introduce first | Surface of substrate covered with |
| precursor (e.g., source | chemisorbed source precursor |
| precursor) to substrate | molecules and excess physisorbed |
| | source precursor molecules |
| Second phase: Introduce purge | Surface of substrate covered with |
| gas (e.g., Ar gas) to substrate | chemisorbed source precursor |
| | molecules |
| Third Phase: Introduce second | Surface of substrate covered with |
| precursor (e.g., reactant | chemisorbed reactant precursor |
| precursor) to substrate | molecules and excess physisorbed |
| | reactant precursor molecules |
| Fourth phase: Introduce purge | Physisorbed reactant precursor |
| gas (e.g., Ar gas) to substrate | molecules removed to obtain a |
| | single ALD layer |

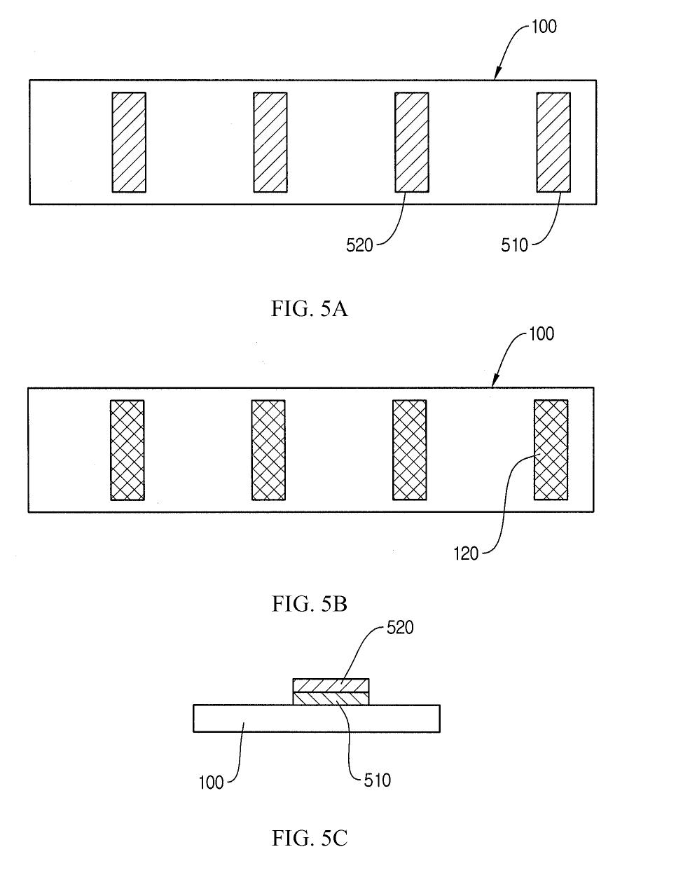

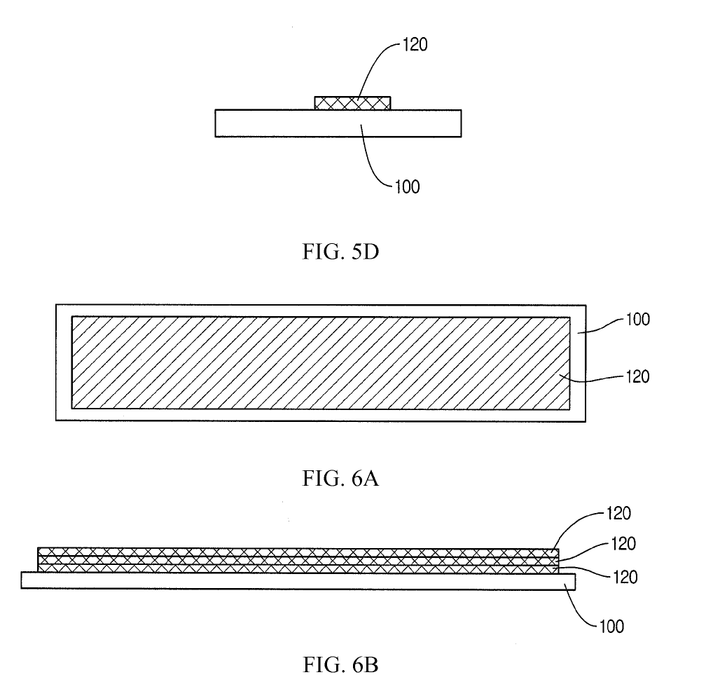

FIG. 5A illustrates a pattern of molecules adsorbed on the substrate 100 when the moving speed of the substrate is excessively fast compared to the rotation speed of the injector rotor, according to one embodiment. If the moving speed of the substrate 100 is excessively fast compared to the rotation speed of the injector rotor, a source precursor layer 510 and a reactant precursor layer 520 are deposited alternatingly on the substrate 100, and the source precursor layer 510 and the reactant precursor layer 520 are spaced apart from each other. Accordingly, reaction between the source precursor and the reactant precursor do not occur, and the atomic layer is not formed on the substrate 100.

FIGS. 5B through 5D show deposition patterns obtained using a rotating reactor assembly according to one embodiment when the rotation speed of the injector rotor is synchronized with the moving speed of the substrate. Referring to FIG. 5B, since a source precursor layer and a reactant precursor layer are formed in the same region, a film 120 may be formed on the substrate 100 via the reaction between the source precursor and the reactant precursor. First, the reactant precursor layer 520 is deposited on the source precursor layer 510 as shown in FIG. 5C. Then, the deposited reactant precursor may react with the source precursor to form single atomic layer 120 as shown in FIG. 5D.

FIG. 6A is a top view of a film formed on the substrate when the moving speed of the substrate is relatively slow as compared to the rotation speed of the injector rotor, and FIG. 6B is a transverse cross-sectional view of the film shown in FIG. 6A. Referring to FIGS. 6A and 6B, if the moving speed of the substrate is sufficiently slow, the source precursor and the reactant precursor may be injected to the substrate multiple times while the substrate passes below the rotating reactor assembly. Accordingly, a film 120 comprising multiple layers may be formed on the substrate while the substrate passes below the rotating reactor assembly. The number of the layers 120 depicted in FIG. 6B is only exemplary. When the moving speed of the substrate 100 is slower, a film comprising a larger number of layers 120 may be formed. That is, by controlling the moving speed of the substrate relatively to the rotation speed of the injector rotor of the rotating reactor assembly, the thickness of the film formed on the substrate may be controlled as desired.

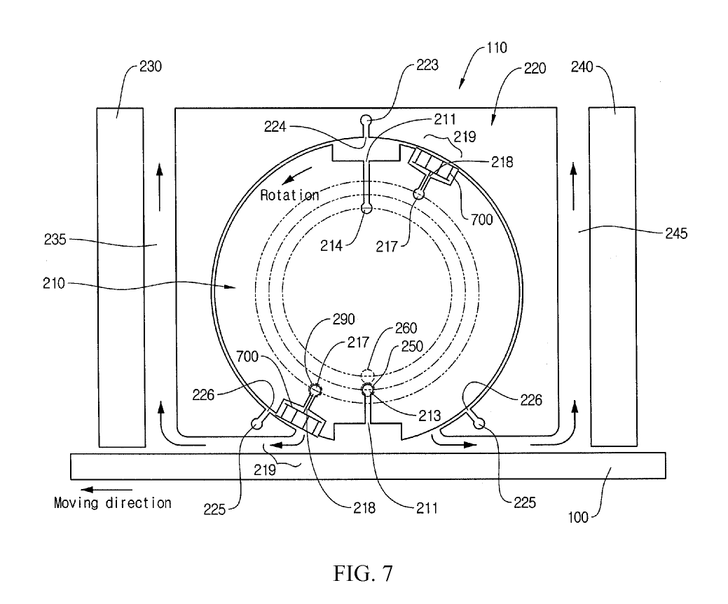

FIG. 7 is a cross-sectional view of a rotating reactor assembly according to one embodiment. An injector rotor 210 of a rotating reactor assembly 110 according to this embodiment may further include one or more third channel(s) 217. Each of the third channel(s) 217 may be connected to one or more third injection hole(s) 218. Each of the third injection hole(s) 218 may be arranged to face a housing 220 in a third recess 219 formed on the surface of the injector rotor 210. The rotating reactor assembly 110 may further include a third intake port 290 for providing a purge gas. When the third channel 217 becomes aligned with the third intake port 290 as the injector rotor 210 rotates, the purge gas introduced through the third intake port 290 may be transferred through the third channel 217 and injected to a substrate 100 through the one or more third injection hole(s) 218.

The purge gas injected through the one or more third injection hole(s) 218 may act as a gas curtain which prevents a source precursor injected through one or more first injection hole(s) 211 and a reactant precursor injected through one or more second injection hole(s) 212 from being introduced into a gap between the injector rotor 210 and the housing 220. For this, each of the third injection hole(s) 218 may be located adjacent to the first injection hole 211 and the second injection hole 212. For example, the third recess 219 wherein the one or more third injection hole(s) 218 is (are) formed may be disposed such that it is adjacent to each end of a first recess 215 and a second recess 216.

Referring to FIG. 7, when the injector rotor 210 rotates in a counter-clockwise direction, a source precursor may be injected through the one or more first injection hole(s) 211 to the substrate 100 passing below the injector rotor 210, and then a purge gas may be injected through the one or more third injection hole(s) 218. Accordingly, excess source precursor physisorbed on the surface of the substrate 100 may be pushed by the purge gas discharged to outside through an exhaust portion 245. Such operation may be similarly applied to the injection of a reactant precursor through the one or more second injection hole(s) 212.

In one embodiment, one or more partition(s) 700 for controlling the flow direction of the purge gas may be disposed in the third recess 219. The partition(s) 700 may serve to prevent the backflow of the purge gas. However, this is only exemplary. In another embodiment, a device for controlling fluid flow other than the partition 700 may be disposed in the third recess 219 or a device for controlling fluid flow may not be disposed.

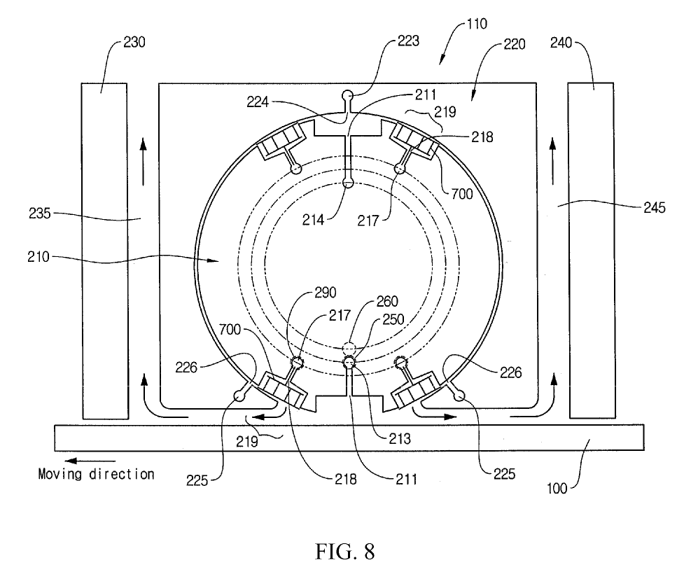

FIG. 8 is a cross-sectional view of a rotating reactor assembly according to one embodiment. A rotating reactor assembly 110 of FIG. 8 is different from that of the embodiment shown in FIG. 7 in that third recesses 219 are formed on both sides of a first recess 215 and on both sides of a second recess 216. In each third recess 219, a third channel 217 for injecting a purge gas and one or more third injection hole(s) 218 may be disposed.

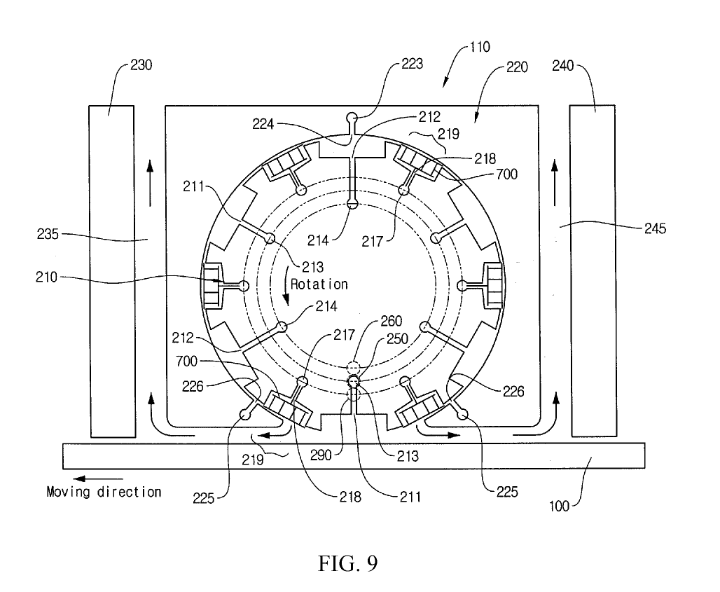

FIG. 9 is a cross-sectional view of a rotating reactor assembly according to one embodiment. In a rotating reactor assembly 110 according to this embodiment, an injector rotor 210 may include a plurality of unit structures comprising a first channel 213 and one or more first injection hole(s) 211 connected thereto. Likewise, the injector rotor 210 may include a plurality of unit structures, each having a second channel 214 and one or more second injection hole(s) 212 connected to the second channel 214o. And, third injection holes 218 for injecting a purge gas may be disposed adjacent to the first injection hole 211 and the second injection hole 212.

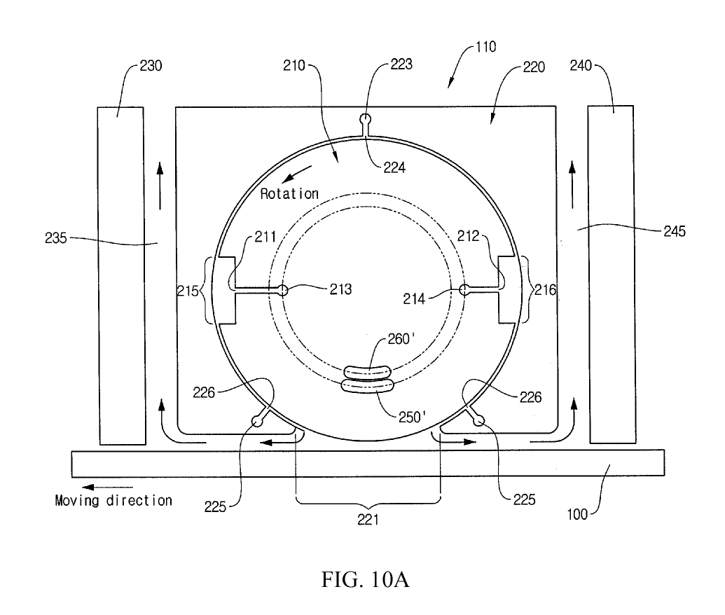

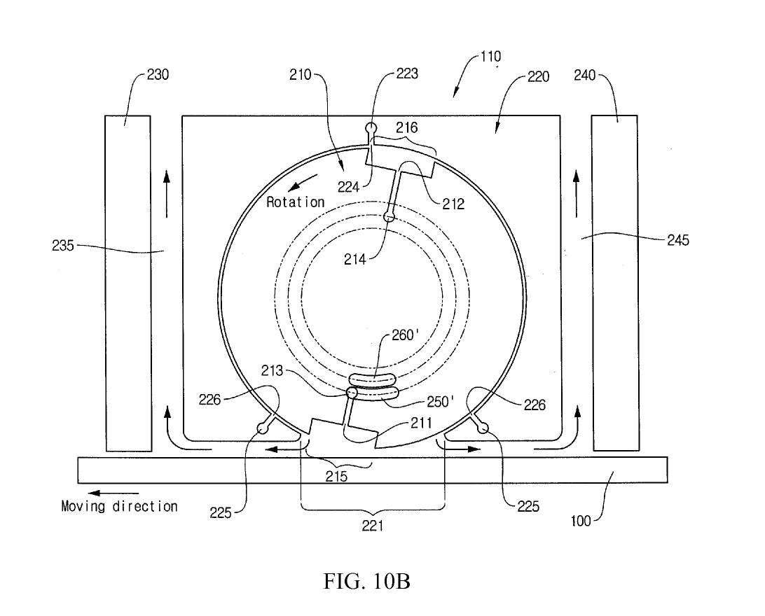

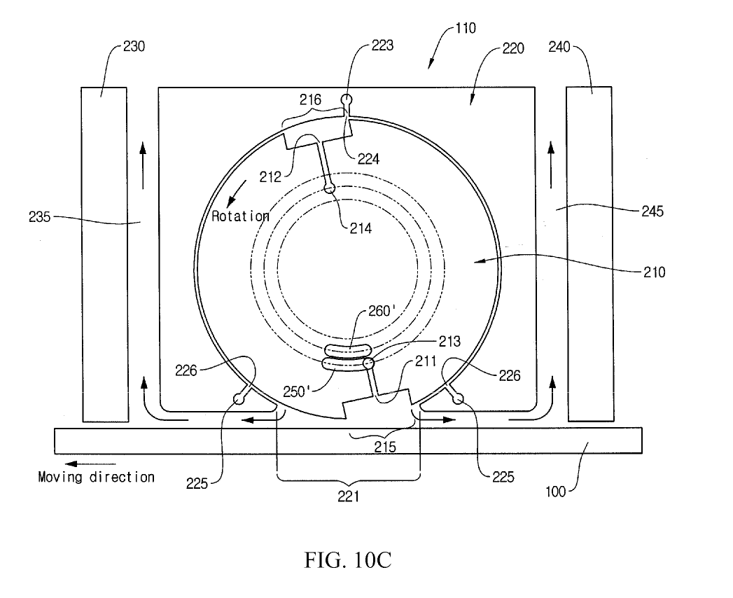

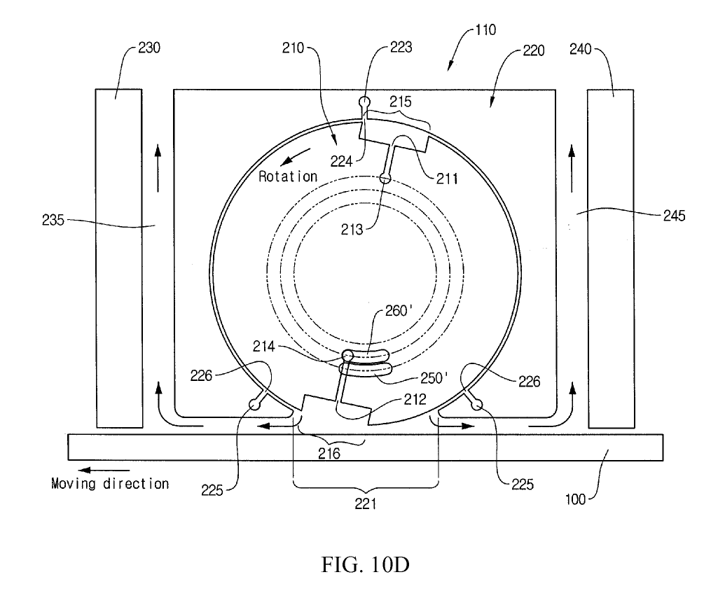

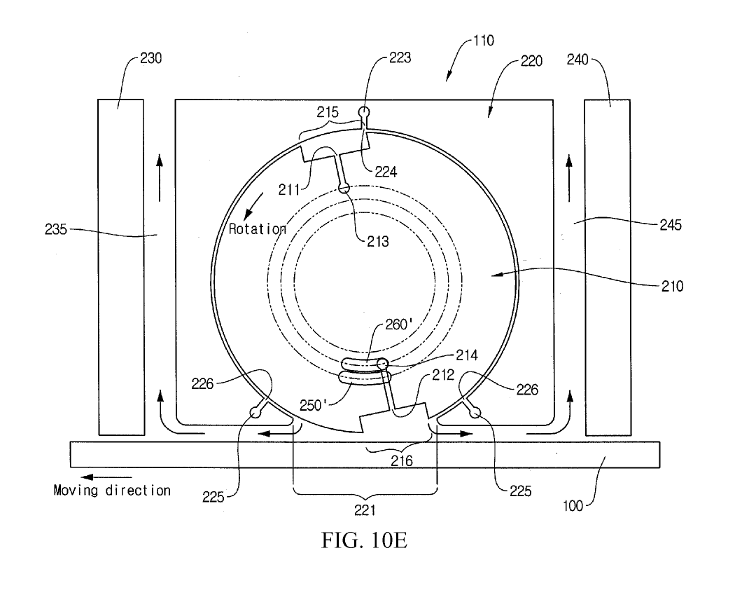

FIGS. 10A through 10E are cross-sectional views of a rotating reactor assembly according to one embodiment in various phases. The rotating reactor assembly 110 according to this embodiment is similar to the rotating reactor assembly of FIG. 4A except that the cross-sectional shape of a first intake port 250′ and a second intake port 260′ is an arc, not a hole. For example, the cross-sectional shape of the first intake port 250′ and the second intake port 260′ may be an arc centered around the rotational axis of the injector rotor 210. However, the shape of the intake port in the embodiment shown in FIG. 10A may also be applied to the rotating reactor assembly according to the embodiment shown in FIG. 4A as well as those according to other embodiments described herein.

Referring to FIG. 10B, when a first channel 213 becomes aligned with the arc-shaped first intake port 250′, a source precursor may be injected through the first channel 213. As shown in FIG. 10C, the source precursor may be continuously injected into the first channel 213 until the first channel 213 moves to the other end of the first intake port 250′. Likewise, as shown in FIG. 10D, a reactant precursor may be injected through a second channel 214, when the second channel 214 becomes aligned with the arc-shaped second intake port 260′. As shown in FIG. 10E, the reactant precursor may be continuously injected into the second channel 214 until the second channel 214 moves to the other end of the second intake port 260′.

In the rotating reactor assembly of FIGS. 10A through 10E, the time during which the source precursor and the reactant precursor are injected through the first channel 213 and the second channel 214 may be determined by the length of the arc-shaped first intake port 250′ and second intake port 260′. For example, the length of the first intake port 250′ located relatively farther from the rotational axis of the injector rotor 210 may be longer than the length of the second intake port 260′ which is relatively closer to the rotational axis of the injector rotor 210. In case the angular speed of the rotating injector rotor 210 is constant, the injection time of the source precursor may be made the same as the injection time of the reactant precursor by making the length of the first intake port 250′ located relatively farther from the rotational axis longer compared to the length of the second intake port 260′. However, this is only exemplary, and the length of the first intake port 250′ and the second intake port 260′ may be determined adequately depending on the properties of the layer to be deposited on the substrate 100.

Although arc-shaped intake ports are described as examples in the embodiment described referring to FIGS. 10A through 10E, the intake ports may have a different shape or configuration in other embodiment allowing the control of the time during which the injector rotor becomes aligned with the channel.

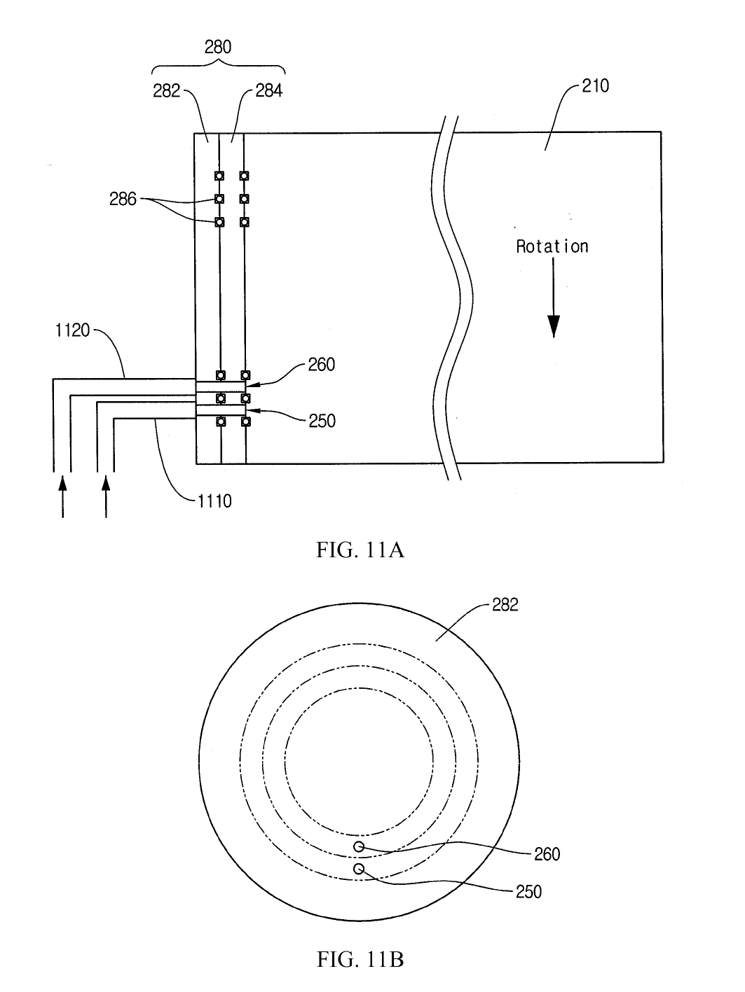

FIG. 11A is a cross-sectional view of a rotating reactor assembly according to one embodiment. FIG. 11B is a front view of a manifolding plate of the rotating reactor assembly shown in FIG. 11, according to one embodiment. In the rotating reactor assembly according to this embodiment, an injector rotor 210 may be provided adjacent to a cover 280, and the cover 280 may have a first intake port 250 and a second intake port 260 formed therein. In one embodiment, the cover 280 includes a manifolding plate 282 and a distribution plate 284. And, an O-ring and/or a ferrofluid for preventing gas leakage may be provided between the manifolding plate 282 and the distribution plate 284 and/or between the distribution plate 284 and the injector rotor 210.

The manifolding plate 282 may be coupled with a conduit 1110, 1120 which is connected to an external source (not shown). A material such as a source precursor or a reactant precursor supplied through the conduit 1110, 1120 may be supplied to the injector rotor 210 through an opening formed on the distribution plate 284. The shape of the opening formed on the distribution plate 284 may be determined adequately depending on the time during which a source precursor, a reactant precursor and/or a purge gas is supplied, such as hole, arc, slot, or the like. And, the distribution plate 284 may be configured to be attachable to and detachable from the rotating reactor assembly. By inserting the distribution plate 284 having an opening with an adequate shape depending on the injection period and time of the source precursor, the reactant precursor and/or the purge gas to the rotating reactor assembly, the properties of the deposited layer can be controlled easily.

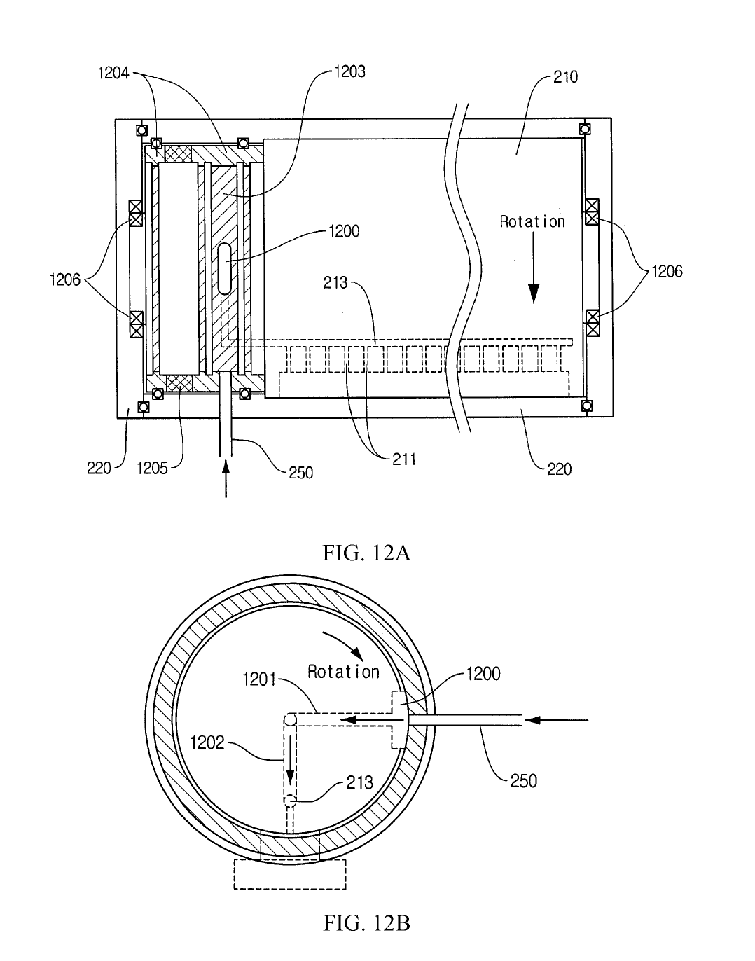

FIG. 12A is a cross-sectional view of a rotating reactor assembly according to one embodiment. FIG. 12B is a transverse cross-sectional view of the portion of the rotating reactor assembly of FIG. 12A where an intake port is connected to an injector rotor, according to one embodiment. In a rotating reactor assembly according to this embodiment, an injector rotor 210 includes an intake opening 1200 formed on the surface of the injector rotor 210. The intake opening 1200 may be provided on the outer circumference of the injector rotor 210 and may be connected through one or more channel(s) 1201, 1203 in the injector rotor 210 to a channel 213 through which a source precursor or a reactant precursor will be injected. As the injector rotor 210 rotates, the location of the intake opening 1200 provided on the outer circumference of the injector rotor 210 is changed. When the intake opening 1200 becomes aligned with an intake port 250, a material injected through the intake port 250 may be supplied to the channel 213 through the intake opening 1200.

In the embodiment shown in FIG. 12B, the intake opening 1200 and the channel 213 are arranged to be perpendicular to each other in a direction perpendicular to the length direction of the injector rotor 210. However, this is only exemplary. In another embodiment, the intake opening 1200 and the channel 213 may be arranged differently.

In the rotating reactor assembly according to the embodiment shown in FIG. 12, a ferrofluid 1203 may be provided in advance between the injector rotor 210 and a housing 220. The ferrofluid 1203 serves to prevent the material injected through the intake port 250 from leaking out through the gap between the injector rotor 210 and the housing 220. Since the flow of the ferrofluid 1203 is controlled by a magnetic field, the rotating reactor assembly according to this embodiment may further comprise a pole piece 1204, a magnet 1205, a magnetic bearing 1206, or the like to control the flow of the ferrofluid 1203.

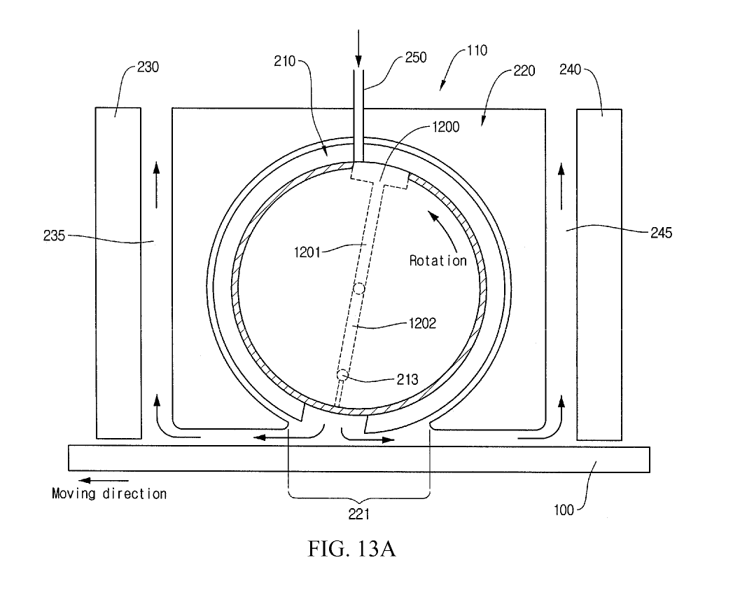

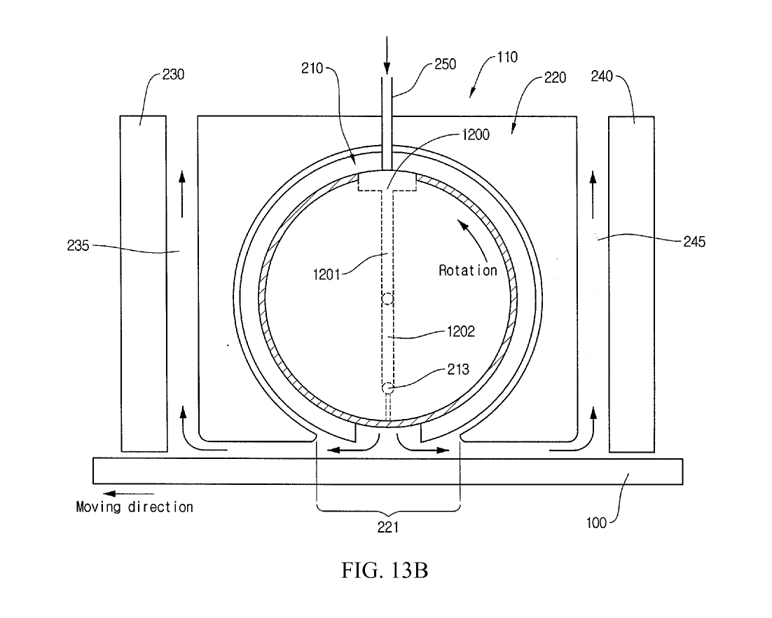

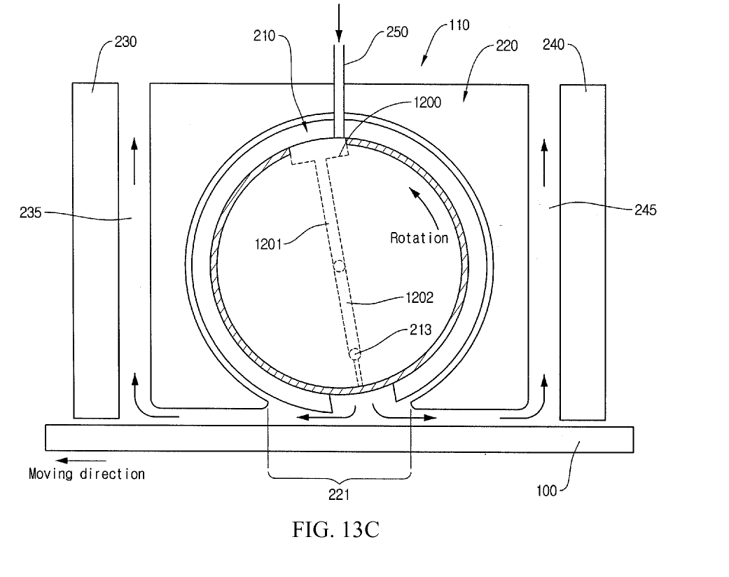

FIGS. 13A through 13C are cross-sectional views of a rotating reactor assembly according to one embodiment in various phases. As shown in FIG. 13A, when an intake opening 1200 of an injector rotor 210 is aligned with an intake port 250, a material injected through the intake port 250 may be supplied to a channel 213 through the intake opening 1200. Even if the injector rotor 210 rotates further as shown in FIG. 13B, the material is continuously supplied to the channel 213 as long as the intake opening 1200 faces the intake port 250. The supply of the material may be performed until the intake opening 1200 reaches the other end of the intake port 250, as shown in FIG. 13C.

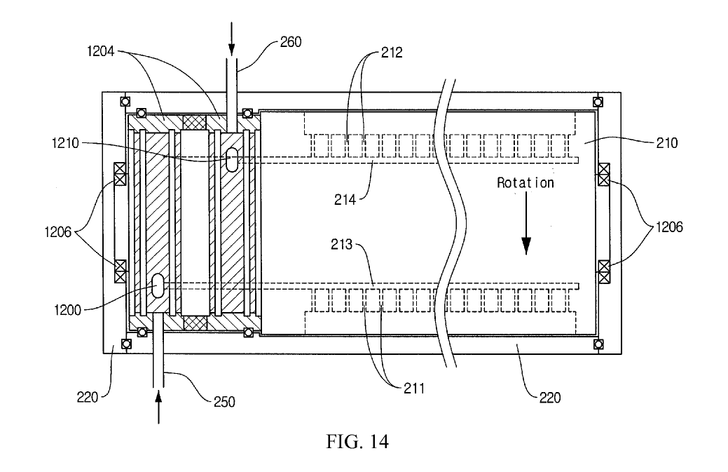

FIG. 14 is a cross-sectional view of another rotating reactor assembly according to one embodiment. The configuration of the rotating reactor assembly according to the embodiment shown in FIG. 14 is the same as that of the rotating reactor assemblies according to the embodiments described referring to FIGS. 12 and 13, except that an injector rotor 210 comprises a first channel 213, a second channel 214, a first intake opening 1200 and a second intake opening 1210, and the rotating reactor assembly comprises a first intake port 250 and a second intake port 260.

The first intake opening 1200 is connected to the first channel 213. As the injector rotor 210 rotates and the first intake opening 1200 becomes aligned with the first intake port 250, a material may be supplied to the first channel 213 through the first intake opening 1200. Meanwhile, the second intake opening 1210 is connected to the second channel 214. When the second intake opening 1210 is aligned with the second intake port 260 as the injector rotor 210 rotates, a material may be supplied to the second channel 214 through the second intake opening 1210.

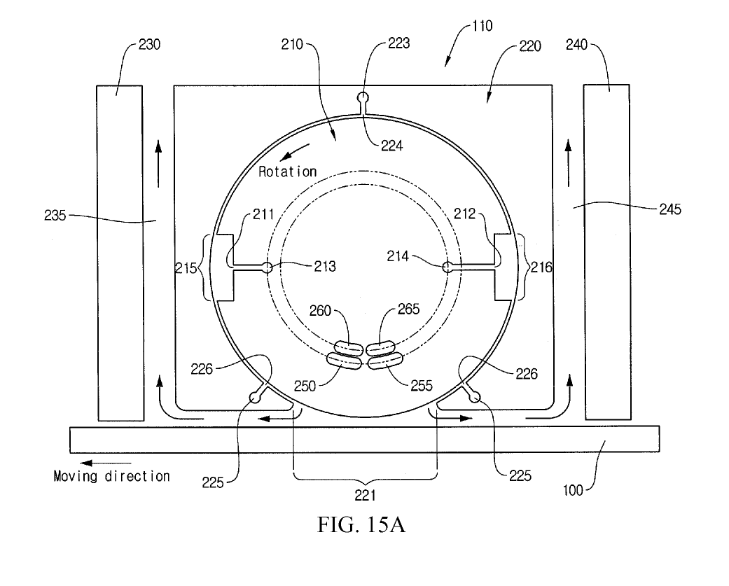

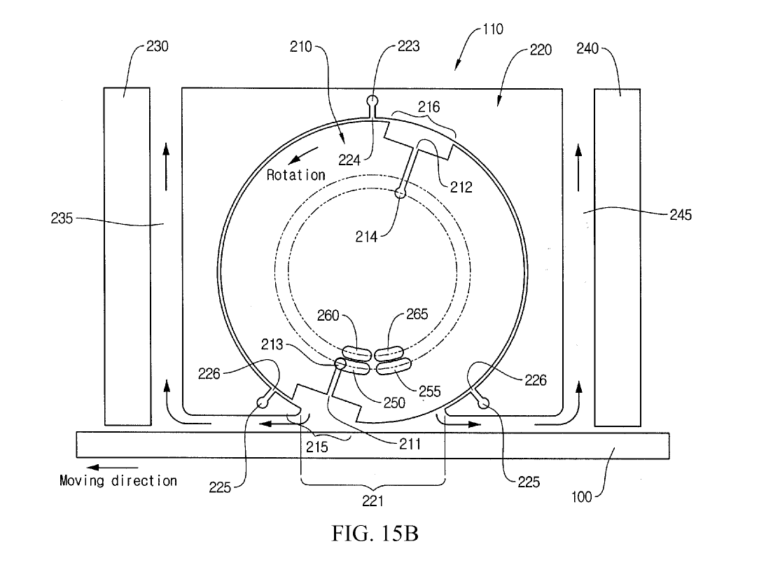

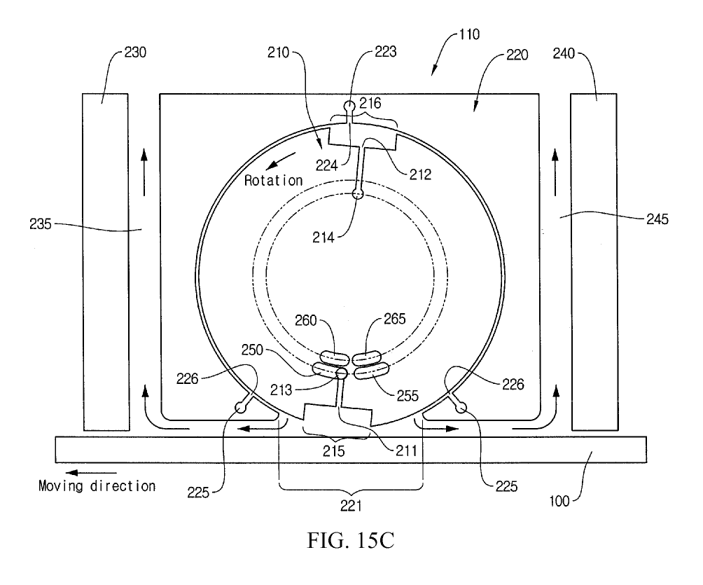

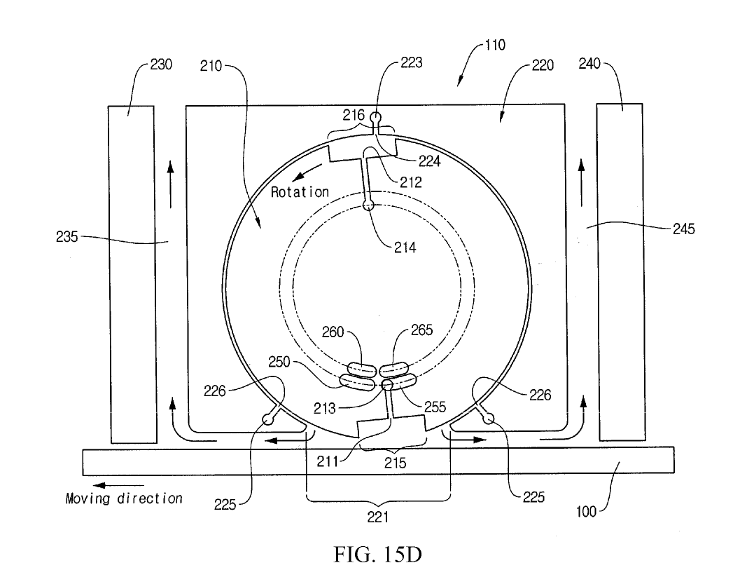

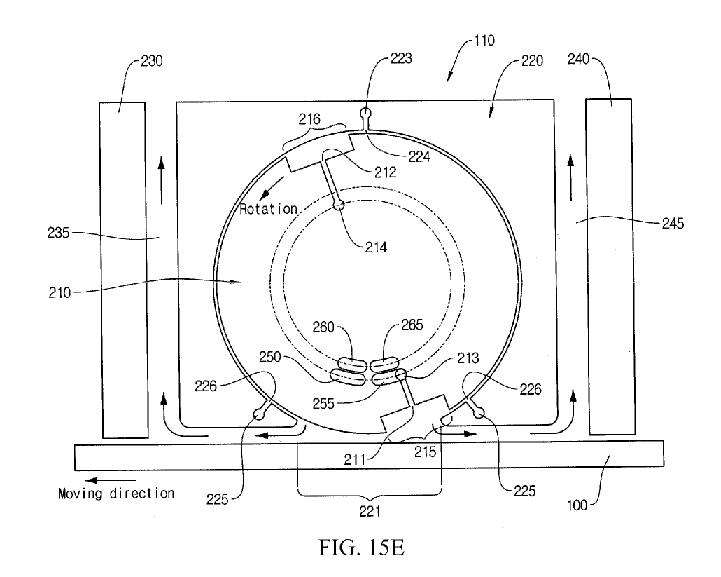

FIGS. 15A through 15E are cross-sectional views of a rotating reactor assembly according to one embodiment in various phases. A rotating reactor assembly 110 according to this embodiment may further comprise a third intake port 255 and a fourth intake port 265 through which a purge gas is introduced in addition to a first intake port 250 through which a source precursor is introduced and a second intake port 260 through which a reactant precursor is introduced. The third intake port 255 may be arranged concentrically with the first intake port 250. And, the fourth intake port 265 may be arranged concentrically with the second intake port 260. In one embodiment, the cross-sectional shape of each of the first to fourth intake ports 250, 260, 255, 265 may be an arc centered around the rotational axis of an injector rotor 210, but is not limited thereto.

Referring to FIGS. 15B and 15C, while a first channel 213 is aligned with the first intake port 250, a source precursor may be supplied through the first channel 213. Referring to FIGS. 15D and 15E, as the injector rotor 210 rotates further, the first channel 213 may pass the first intake port 250 and be aligned with the third intake port 255 disposed concentrically with the first intake port 250. While the first channel 213 is aligned with the third intake port 255, a purge gas may be supplied through the first channel 213. Accordingly, purging by the purge gas may be carried out following the injection of the source precursor and, thus, excess source precursor physisorbed on a substrate 100 may be removed.

Although a process whereby injection of the source precursor and purging are carried out while the first channel 213 passes the first intake port 250 and the third intake port 255 was described referring to FIGS. 15B through 15E, the injection of a reactant precursor and purging may be carried out similarly while a second channel 214 passes the second intake port 260 and the fourth intake port 265.

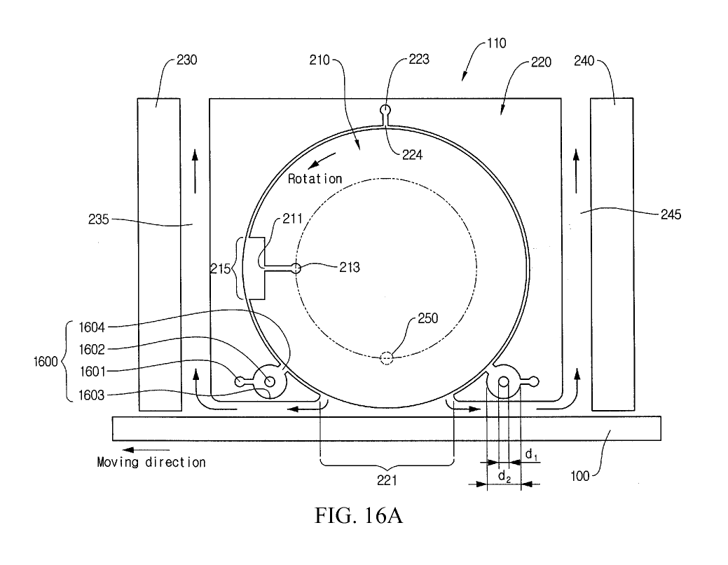

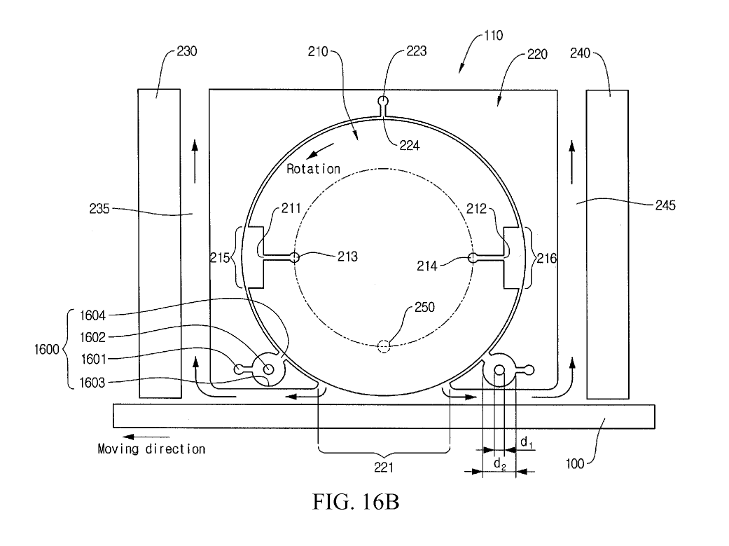

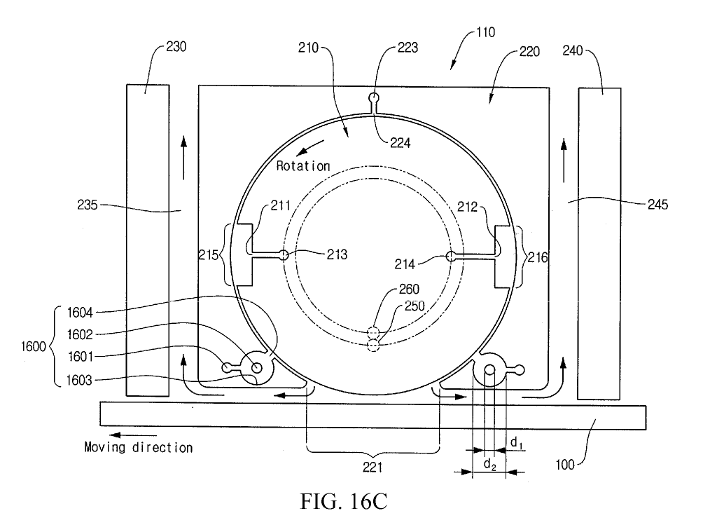

FIG. 16A is a cross-sectional view of a rotating reactor assembly according to one embodiment. In a rotating reactor assembly according to this embodiment, a housing 220 may include a plasma generator 1600 for supplying radicals formed by a plasma. In one embodiment, the plasma generator 1600 may comprise a channel 1601 through which a reactant gas for generating a plasma is injected, an internal electrode 1602 and an external electrode 1603, and one or more injection hole(s) 1604 for supplying radicals formed by the plasma. The rotating reactor assembly according to this embodiment may comprise the plasma generator 1600 in singular or plural numbers. For example, the plasma generators 1600 may be disposed on both sides of the opening 221 of the housing 220. However, the present invention is not limited thereto.

When the reactant gas is injected into the plasma generator 1600 through the channel 1601, a voltage may be applied between the internal electrode 1602 and the external electrode 1603 to generate a plasma from the reactant gas between the internal electrode 1602 and the external electrode 1603. The external electrode 1603 may be an outer wall enclosing the internal electrode 1602. For example, at least a part of the housing 220 may be formed with a conducting material and a voltage may be applied thereto, so that the function of the external electrode 1603 can be exerted. However, this is only exemplary. In another embodiment, the external electrode 1603 may be provided as a separate electrode independently of the housing 220.

In one embodiment, a direct current (DC) voltage may be applied between the internal electrode 1602 and the external electrode 1603. For example, the DC voltage applied between the internal electrode 1602 and the external electrode 1603 may be from about 800 V to about 1.5 kV. Also, a DC pulse voltage with a frequency of about 500 kHz or lower may be applied between the internal electrode 1602 and the external electrode 1603.

In one embodiment, the outer diameter of the internal electrode 1602 may be from about 3 to about 6 mm. And, the inner diameter of the external electrode 1603 may be from about 10 to about 20 mm. The reactant gas may be injected between the internal electrode 1602 and the external electrode 1603 configured as described above. The flow rate of the reactant gas may be about 5 to 100 sccm. And, the injection hole 1604 for supplying the plasma generated from the reactant gas may have a shape of a slit having a width of about 2 to 4 mm.

A radical-assisted ALD process may be performed on a substrate using the rotating reactor assembly according to the embodiment described referring to FIG. 16A. Some examples of the radical-assisted ALD process that may be performed using the rotating reactor assembly according to this embodiment is described hereinafter. However, the process that may be performed using the rotating reactor assembly is not limited thereto.

### 1. Source as Followed by Ar Followed by Plasma (Radicals) Followed by Ar

First, while injecting Ar gas through the channel 223 and one or more injection hole(s) 224 formed at the upper portion of the housing 220, a source precursor may be injected to a substrate 100 through a channel 213 and one or more injection hole(s) 211 formed on an injector rotor 210. The source precursor may also be supplied by bubbling using the Ar gas. Alternatively, the source precursor may be supplied by vapor drawing or direct liquid injection (DLI). That is to say, the supply method is not particularly limited. In one embodiment, the source precursor may be trimethylaluminum (TMA, (CH₃)₃Al) and an Al₂O₃ film may be formed on the substrate 100 using the same. Alternatively, the source precursor may be dimethylamuninumhydride (DMAH) [(CH₃)₂AlH] or methylethylaminoaluminum hydride [(AlN(CH₃)(C₂H₅)H₂)] and an AN film or an Al film may be formed on the substrate 100 using the same.

As the injector rotor 210 rotates, the source precursor is injected to the substrate 100, and then the Ar gas is injected to the substrate 100. The injected Ar gas may remove source precursor molecules or excess source precursor material physisorbed to the substrate 100. Subsequently, radicals of a reactant precursor supplied by the plasma generator 1600 may be injected to the substrate 100. For example, when an Al₂O₃ film is desired to be formed, O₂ or N₂O may be supplied to the plasma generator 1600 as the reactant precursor. And, when an AN film is desired to be formed, N₂ or NH₃ may be supplied to the plasma generator 1600 as the reactant precursor. And, when an Al film is desired to be formed, H₂ may be supplied to the plasma generator 1600 as the reactant precursor. Furthermore, Ar gas may be included in the gas supplied to the plasma generator 1600 for stabilizing the plasma.

The supply of the radicals by the plasma generator 1600 needs not necessarily be continuous. For example, after the injection of the source gas and the injection of the Ar gas to the substrate 100 are completed, a voltage may be applied to the plasma generator 1600 to supply radicals of the reactant precursor to the substrate. Then, after blocking power supply to the plasma generator 1600, excess materials may be removed from the substrate 100 using the Ar gas.

### 2. Source as Followed by Ar as Followed by Plasma (Radicals) Followed by Ar* Followed by Ar

In one embodiment, after the injection of the source gas and the injection of the Ar gas to the substrate 100 are completed, the reactant precursor may be injected to the plasma generator 1600 before applying a voltage to the plasma generator 1600, in order to prevent the source precursor from being introduced to the plasma generator 1600. The reactant precursor supplied to the plasma generator 1600 is injected to the substrate 100, and may form a film on the substrate by reacting with the source precursor on the substrate. After a predetermined time passes, a voltage may be applied to the plasma generator 1600 while supplying Ar gas to the plasma generator 1600. As a result, argon plasma may be generated and injected to the substrate 100. The argon plasma may be injected to the substrate 100 until the source precursor is injected again through the one or more injection hole(s) 211. While the source precursor is injected, argon plasma may not be generated.

By treating the substrate 100 with Ar* (activated Ar or Ar radical), the density of the film formed on the substrate 100 may be improved or the bonding state of the molecules present on the surface of the substrate 100 may be changed. For example, the surface of the substrate 100 may be treated with Ar*, so that the bonding between the molecules on the surface of the film formed on the substrate 100 may be broken or the molecules may remain unoccupied or have dangling bonds until the source precursor is injected in the next stage.

Since Ar* has a very short lifetime, after the surface of the substrate 100 is treated with Ar*, Ar* may be converted back to Ar. After the conversion, Ar may act as the purge gas as described above. Therefore, following the surface of the substrate 100 with Ar*, purging by Ar gas is performed naturally.

### 3. Source as Followed by Ar as Followed by Ar* Followed by Plasma (Radicals) Followed by Ar* Followed by Ar

In one embodiment, Ar gas may be supplied to the plasma generator 1600 before the reactant precursor is supplied by the plasma generator 1600. As a result, the substrate 100 is exposed first to Ar* before the reactant precursor is exposed to the radical. Subsequently, by changing the gas supplied by the plasma generator 1600 from the Ar gas to the reactant precursor, radicals of the reactant precursor may be injected to the substrate. Then, by changing the gas supplied by the plasma generator 1600 again to the Ar gas, Ar* may be injected to the substrate.

FIG. 16B is a cross-sectional view of a rotating reactor assembly according to one embodiment. The rotating reactor assembly shown in FIG. 16B is similar to the rotating reactor assembly of FIG. 16A, except that an injector rotor 210 includes a first channel 213 and a second channel 214 and further comprises one or more first injection hole(s) 211 and one or more second injection hole(s) 212. The first channel 213 and the second channel 214 may be alternatingly connected to one intake port 250. As a result, the same precursor may be injected through the one or more first injection hole(s) 211 and the one or more second injection hole(s) 212. Accordingly, deposition rate can be improved since the amount of the precursor injected per revolution of the injector rotor 210 can be increased.

FIG. 16C is a cross-sectional view of a rotating reactor assembly according to one embodiment. The rotating reactor assembly shown in FIG. 16C is similar to that of the rotating reactor assembly according to the embodiment described referring to FIG. 16B, except that the rotating reactor assembly comprises a first intake port 250 and a second intake port 260. As an injector rotor 210 rotates, the first intake port 250 may be connected to a first channel 213 and the second intake port 260 may be connected to a second channel 214 in accordance with the rotation speed of the injector rotor 210. Accordingly, two different source precursors may be alternatingly injected to a substrate 100.

For example, TMA may be injected through one or more first injection hole(s) 211 and tertamethylethylaminozirconium (TEMAZr, [(CH₃)(C₂H₅)N]₄Zr) may be injected through one or more second injection hole(s) 212. In this case, an Al₂O₃ layer formed via a reaction between the TMA and radicals injected by a plasma generator 1600 and a ZrO₂ layer formed via a reaction between the TEMAZr and the radicals injected by the plasma generator 1600 may be deposited alternatingly on the substrate 100.

Although the present invention has been described above with respect to several embodiments, various modifications can be made within the scope of the present invention. Accordingly, the disclosure of the present invention is intended to be illustrative, but not limiting, of the scope of the invention, which is set forth in the following claims.

What is claimed is:

1. A rotating reactor assembly comprising:
an injector rotor configured to rotate about an axis, wherein at least one channel extending longitudinally along the injector rotor and at least one injection hole connected to the channel are formed in the injector rotor; and
a housing configured to mount the injector rotor and at least partially enclose the injection rotor, wherein at least one intake port for conveying a material is formed in the housing to connect to the at least one channel with rotation of the injector rotor, the material injected onto a substrate through an opening formed in the housing responsive to the at least one channel connected to the intake port.

2. The rotating reactor assembly according to claim 1, wherein a recess is formed in a circumference of the injector rotor, and wherein the at least one injection hole is disposed in the recess.

3. The rotating reactor assembly according to claim 1, wherein an intake opening connected to the channel is formed on a circumference of the injector rotor.

4. The rotating reactor assembly according to claim 1, wherein the at least one channel comprise a first channel and a second channel, and the at least one injection hole comprises at least one first injection hole connected to the first channel and at least one second injection hole connected to the second channel.

5. The rotating reactor assembly according to claim 4, wherein the at least one intake port comprises a first intake port through which a first material is introduced and a second intake port through which a second material is introduced, and wherein the first channel is connected to the first intake port and the second channel is connected to the second intake port periodically with rotation of the injector rotor.

6. The rotating reactor assembly according to claim 5, wherein the first channel is connected to the first intake port during a first period and the second channel is connected to the second intake port during a second period.

7. The rotating reactor assembly according to claim 5, wherein the first intake port and the second intake port are arranged in a direction perpendicular to the axis of the injector rotor.

8. The rotating reactor assembly according to claim 7, wherein the first channel and the first intake port are disposed at a first distance from the rotational axis of the injector rotor, and the second channel and the second intake port are disposed at a second distance from the rotational axis of the injector rotor, the first and second distances being different from each other.

9. The rotating reactor assembly according to claim 4, wherein a third channel extending longitudinally in the injector rotor and at least one third injection hole connected to the third channel are formed in the injector rotor, wherein a purge gas is injected onto the substrate through the at least one third injection hole.

10. The rotating reactor assembly according to claim 1, wherein the injector rotor is of a cylindrical shape.

11. The rotating reactor assembly according to claim 1, wherein a fourth channel for conveying a purge gas and at least one fourth injection hole connected to the fourth channel is formed in the housing.

12. The rotating reactor assembly according to claim 1, wherein the housing further comprises a plasma generator for injecting radicals generated by plasma to a region between the injector rotor and the housing.

13. The rotating reactor assembly according to claim 1, wherein at least one exhaust portion is formed in the housing to discharge materials from the rotating reactor assembly.

14. The rotating reactor assembly according to claim 1, further comprising
a cover on which the at least one intake port is formed; and
a conduit connected to the intake port for supply the material.

15. The rotating reactor assembly according to claim 1, wherein each of the at least one intake port has a shape of a hole or an arc.

16. The rotating reactor assembly according to claim 1, wherein the at least one intake port for conveying the material is connected to the at least one channel periodically.

17. A method for depositing a film on a substrate, the method comprising:
conveying a material to an intake port formed in a housing;
rotating the injector rotor within the housing, the injector rotor having at least one channel for carrying the material;
connecting the at least one channel to the intake port responsive to the injector rotor rotating to a predetermined location; and
injecting the material onto a substrate through the intake port, the at least one channel and an opening formed in the housing and responsive to connecting the at least one channel to the intake port.

18. The method according to claim 17, further comprising injecting a purge gas onto the substrate through the opening formed in the housing.

19. The method according to claim 17, further comprising connecting an input port for carrying the purge gas to the at least one channel in injector rotor responsive to the injector rotor rotating to another predetermined location.

20. The method according to claim 17, further comprising, injecting radicals generated by plasma onto the substrate through the opening formed in the housing.

21. The method according to claim 17, wherein the at least one channel is connected to the intake port periodically.
